(19) United States
(12) Patent Application Publication
(10) Pub. No.: US 2020/0361123 A1
(43) Pub. Date: Nov. 19, 2020

(54) PREPARATION METHOD OF SPLICING IMPRINT TEMPLATE AND CAVITY TEMPLATE

(71) Applicant: BOE Technology Group Co., Ltd., Beijing (CN)

(72) Inventors: Wei TAN, Beijing (CN); Kang GUO, Beijing (CN); Xin GU, Beijing (CN); Xiao ZHANG, Beijing (CN)

(21) Appl. No.: 16/954,626

(22) PCT Filed: Nov. 11, 2019
(86) PCT No.: PCT/CN2019/117133

§ 371 Date: Jun. 17, 2020

(30) Foreign Application Priority Data
Nov. 19, 2018 (CN) 201811376982.9

(51) Int. Cl. B29C 33/38; G03F 7/00

(52) U.S. Cl. CPC B29C 33/3857; B29C 2033/3871; G03F 7/0002

(57) ABSTRACT

The present disclosure provides a preparation method of a splicing imprint template including a first splicing area and a second splicing area adjacent to each other, the preparation method including: forming a first splicing imprint pattern in the first splicing area on a base substrate; forming a sacrificial layer on a side surface of the first splicing imprint pattern facing away from the base substrate; forming a second template glue in the second splicing area on the base substrate; patterning the second template glue in the second splicing area by a preset cavity template; curing and demolding the second template glue; and removing the sacrificial layer through a specific film removing process. The present disclosure further provides a splicing imprint template and a cavity template.

### CROSS-REFERENCE TO RELATED APPLICATION

This is a National Phase Application filed under 35 U.S.C. 371 as a national stage of PCT/CN2019/117133, filed Nov. 11, 2019, an application claiming the benefit of Chinese Application No. 201811376982.9, filed Nov. 19, 2018, the content of each of which is hereby incorporated by reference in its entirety.

### TECHNICAL FIELD

The present disclosure relates to the technical field of nano-imprinting technologies, and in particular relates to a preparation method of a splicing imprint template and a cavity template.

### BACKGROUND

When a large-size imprint template is prepared, a pattern layer for imprinting needs to be formed by splicing subpatterns for imprinting. The splicing method includes separate splicing and overlap splicing. When separate splicing is adopted, the obtained pattern layer for imprinting has a wider splicing seam, and when overlap splicing is adopted, the obtained pattern layer has a larger splicing segment difference in the overlap area.

As can be seen, the pattern layer for imprinting prepared by the existing splicing methods has obvious defects.

### SUMMARY

To solve at least one of the problems in the related art, the present disclosure provides a preparation method of a splicing imprint template and a cavity template.

In a first aspect, an embodiment of the present disclosure provides a preparation method of a splicing imprint template, wherein the splicing imprint template includes: a first splicing area and a second splicing area adjacent to each other, and the preparation method includes: forming a first splicing imprint pattern in the first splicing area on a base substrate; forming a sacrificial layer on a side surface of the first splicing imprint pattern facing away from the base substrate, the sacrificial layer covering at least part of the first splicing area close to the second splicing area, and the sacrificial layer, the first splicing imprint pattern and a second splicing imprint pattern to be formed subsequently being configured such that under a film removing process, the sacrificial layer is removed while the first splicing imprint pattern and the second splicing imprint pattern remain; forming a second template glue in the second splicing area on the base substrate; patterning the second template glue in the second splicing area by a cavity template; curing and demolding the second template glue; and removing the sacrificial layer by the film removing process.

In some embodiments, the sacrificial layer covers the entire first splicing area.

In some embodiments, a material of the sacrificial layer includes: a degradable material; and the step of removing the sacrificial layer through the film removing process includes: degrading the sacrificial layer through a degradation process.

In some embodiments, the degradable material includes: a degradable imprint glue.

In some embodiments, a material of the sacrificial layer includes: a water soluble material; and the step of removing the sacrificial layer through the film removing process includes: dissolving the sacrificial layer with an aqueous solvent.

In some embodiments, the water soluble material includes: at least one of a polyvinyl alcohol resin and a polycaprolactone resin.

In some embodiments, after the step of removing the sacrificial layer through the film removing process, the method further includes: drying the imprint template.

In some embodiments, the cavity template includes: a first imprint structure and a second imprint structure connected to each other; the first imprint structure includes: a support layer, and an imprint pattern layer located on and protruding from a first surface of the support layer; the second imprint structure extends out of the support layer along a direction parallel to the first surface, and is located on a side of a plane of the first surface facing away from the imprint pattern layer so that a distance exists between a surface, close to the imprint pattern layer, of the second imprint structure and the first surface; and the step of patterning the second template glue in the second splicing area by the cavity template includes: aligning the cavity template to the second template glue, wherein an orthographic projection of the first imprint structure on the base substrate covers the second splicing area, and an orthographic projection of the second imprint structure on the base substrate falls into an orthographic projection of the sacrificial layer on the base substrate; and imprinting the second template glue by the cavity template to pattern the second template glue in the second splicing area.

In some embodiments, during the process of patterning the second template glue in the second splicing area by the cavity template, a side of the first imprint structure facing the second imprint structure is located on the same plane as a side surface of the first splicing imprint pattern facing the second splicing area.

In a second aspect, an embodiment of the present disclosure further provides a cavity template, including: a first imprint structure and a second imprint structure connected to each other; wherein the first imprint structure includes: a support layer, and an imprint pattern layer located on and protruding from a first surface of the support layer; and, the second imprint structure extends out of the support layer along a direction parallel to the first surface, and is located on a side of a plane of the first surface facing away from the imprint pattern layer so that a distance exists between a surface, close to the imprint pattern layer, of the second imprint structure and the first surface.

In some embodiments, an imprint surface of the second imprint structure is a plane.

In some embodiments, the first and second imprint structures are integrally formed.

### BRIEF DESCRIPTION OF THE DRAWINGS

FIG. 1 is a schematic cross-sectional view illustrating preparing an imprint template by overlap splicing in the related art;

FIG. 2 is a flowchart of a preparation method in which corresponding splicing imprint patterns are formed in two adjacent splicing area respectively according to the present disclosure;

FIG. 3 is a schematic cross-sectional view illustrating forming a first splicing imprint pattern in a first splicing area according to the present disclosure;

FIG. 4 is a schematic cross-sectional view illustrating forming a sacrificial layer on the first splicing imprint pattern according to the present disclosure;

FIG. 5 is a schematic cross-sectional view illustrating forming a second template glue in the second splicing area according to the present disclosure;

FIG. 6a is a schematic cross-sectional view illustrating patterning the second template glue;

FIG. 6b is a schematic cross-sectional view illustrating patterning the second template glue;

FIG. 7 is a schematic cross-sectional view illustrating separating the preset cavity template from the second template glue;

FIG. 8 is a schematic cross-sectional view illustrating removing the sacrificial layer through a specific film removing process to obtain a first splicing imprint pattern and a second splicing imprint pattern; and

FIG. 9 is a schematic cross-sectional view of a cavity template provided by an embodiment of the disclosure.

### DETAILED DESCRIPTION OF THE EMBODIMENTS

To improve understanding of the technical solution of the present disclosure for those skilled in the art, the splicing imprint template, the preparation method thereof and the cavity template according to the present disclosure will be described below in detail in conjunction with the accompanying drawings.

Example embodiments will be described more sufficiently below with reference to the accompanying drawings, but which may be embodied in different forms and should not be construed as limited to the embodiments set forth herein. Rather, these embodiments are provided so that this disclosure will be thorough and complete, and will fully convey the scope of the disclosure to those skilled in the art.

The terminology used herein is for the purpose of describing specific embodiments only and is not intended to limit the disclosure. As used herein, the singular forms “a”, “an” and “the” are intended to include the plural forms as well, unless the context clearly indicates otherwise. It will be further understood that as used herein, the terms “comprise” and/or “consist of . . . ” specify the presence of stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various elements, these elements should not be limited by these terms. These terms are only used to distinguish one element from another. Thus, a first element, component, or part discussed below could be termed a second element, component, or part without departing from the teachings of the present disclosure.

Embodiments described herein may be described with reference to plan and/or cross-sectional views in idealized representations of the present disclosure. Accordingly, the example illustrations may be modified in accordance with manufacturing techniques and/or tolerances. Accordingly, the embodiments are not limited to the embodiments shown in the drawings, but include modifications of configurations formed based on a manufacturing process. Thus, the regions illustrated in the figures have schematic properties, and the shapes of the regions shown in the figures illustrate specific shapes of regions of elements, but are not intended to be limiting.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the related art and the present disclosure, and will not be interpreted in an idealized or overly formal sense unless expressly so defined herein.

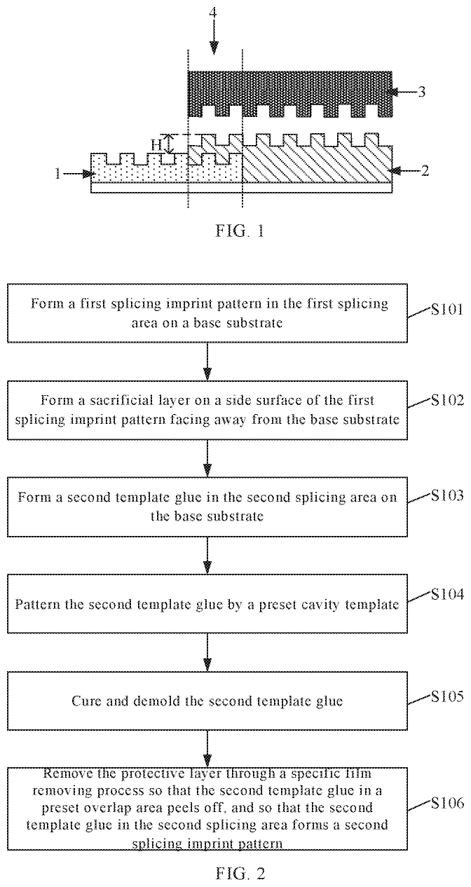

FIG. 1 is a schematic cross-sectional view illustrating preparing an imprint template by overlap splicing in the related art. As shown in FIG. 1, the process of forming imprint splicing patterns sequentially in two adjacent splicing areas is roughly as follows. Firstly, an imprint splicing pattern 1 is formed in one of the splicing areas; then, a template glue 2 is evenly coated at different positions in the other of the splicing areas; and next, a cavity template 3 is used to pattern the template glue 2.

During the process of patterning the template glue 2 by the cavity template 3, overlapped glue will inevitably occur, causing part of the template glue to overflow to a surface of the imprint splicing pattern 1, and part of the imprint splicing pattern 1 corresponding to the preset overlap area 4 to be covered. In order for continuity of the two imprint splicing patterns in the two adjacent splicing areas, the template glue 2 in the preset overlap area 4 also needs to be patterned. In order to ensure that the template glue 2 in the preset overlap area 4 can be patterned, the template glue 2 needs to be coated in a large thickness so that the template glue overflowing to the preset overlap area 4 can be patterned.

Although the conventional preparation methods can solve the problem with continuity of the imprint splicing pattern, as can be seen from FIG. 1, the imprint splicing pattern formed later has a thickness obviously greater than the adjacent imprint splicing pattern 1 that is formed earlier. As a result, there is a great segment difference H between the two imprint splicing patterns, which may have a serious influence on the imprinting effect of the imprint template.

In order to solve the above technical problem, the present disclosure provides an imprint template, a preparation method thereof and a cavity template.

In the preparation method of a splicing imprint template provided by the embodiment of the present disclosure, the splicing imprint template includes a first splicing area and a second splicing area adjacent to each other, a first splicing imprint pattern formed the first splicing area, and a second splicing imprint pattern formed the second splicing area.

FIG. 2 is a flowchart of a preparation method in which corresponding splicing imprint patterns are formed in two adjacent splicing area respectively according to the present disclosure. As shown in FIG. 2, the step of forming the first splicing imprint pattern and the second splicing imprint pattern in the adjacent first and second splicing areas respectively includes the following specific steps S101 to S106.

At step S101, a first splicing imprint pattern 8 is formed in the first splicing area on a base substrate.

FIG. 3 is a schematic cross-sectional view of a first splicing imprint pattern formed within a first splicing area according to the present disclosure. As shown in FIG. 3, first, a first template glue is coated in the first splicing area 6 on the base substrate 5. The first template glue includes a monomer, a prepolymer, a photoinitiator, and other additives, and the main resin of the template glue is an acrylate resin, an epoxy resin, or the like, with a coating thickness of 3 um to 4 um. The coating method includes, but is not limited to, spin coating, slot coating, inkjet printing and slot-die coating. Then, the template glue is imprinted by a first cavity template (not shown), and the patterned first template glue is cured and demolded to obtain the first splicing imprint pattern 8. The curing process include, but is not limited to, thermal curing and photo curing. It should be noted that the first cavity template is a template provided in advance for preparing the first splicing imprint pattern 8, and the specific structure thereof is not limited.

The first splicing imprint pattern 8 prepared by the above process is not water soluble or degradable.

At step S102, a sacrificial layer is formed on a side surface of the first splicing imprint pattern facing away from the base substrate.

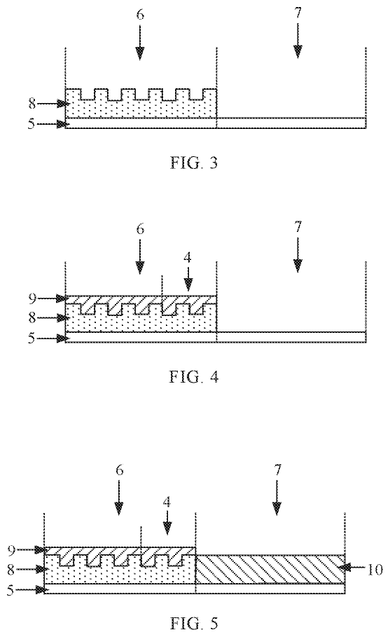

FIG. 4 is a schematic cross-sectional view illustrating forming a sacrificial layer on the first splicing imprint pattern according to the present disclosure. As shown in FIG. 4, a sacrificial layer 9 is formed on the first splicing imprint pattern 8. The sacrificial layer 9 covers at least part (the preset overlap area 4) of the first splicing area close to the second splicing area. The preset overlap area 4 is a side surface of the first splicing imprint pattern 8 facing away from the base substrate 5 and close to the second splicing area 7.

In the present disclosure, the preset overlap area 4 in the first splicing area is an area set according to the overlap condition of the second template glue in a preliminary imprint experiment. The specific shape and size of the preset overlap area 4 is not limited in the technical solution of the present disclosure.

Preferably, the sacrificial layer 9 completely covers a side surface of the first splicing imprint pattern 8 facing away from the base substrate 5, the specific beneficial effect of which will be described later. It should be noted that FIG. 3 only exemplifies the case where the sacrificial layer 9 completely covers a side surface of the first splicing imprint pattern 8 facing away from the base substrate 5.

In the present disclosure, the sacrificial layer 9, the first splicing imprint pattern 8 and a second splicing imprint pattern to be formed subsequently are configured such under a specific film removing process, the sacrificial layer 9 is removed while the first splicing imprint pattern 8 and the second splicing imprint pattern remain.

As an alternative implementation, a material of the sacrificial layer includes: a degradable material; and further, the degradable material includes: a degradable imprint glue. Further optionally, the degradable imprint glue specifically includes a degradable resin.

As another alternative implementation, a material of the sacrificial layer includes: a water soluble material; and further, the water soluble material includes: at least one of a polyvinyl alcohol resin and a polycaprolactone resin.

At step S103, a second template glue is formed in the second splicing area on the base substrate.

FIG. 5 is a schematic cross-sectional view illustrating forming a second template glue in the second splicing area according to the present disclosure. As shown in FIG. 5, a second template glue 10 is precisely coated on the second splicing area 7 through a coating process. The second template glue 10 includes a monomer, a prepolymer, a photoinitiator, and other additives, and the main resin of the template glue is an acrylate resin, an epoxy resin, or the like, with a coating thickness of 5 um to 6 um. The coating method includes, but is not limited to, spin coating, slot coating, inkjet printing and slot-die coating.

In the present disclosure, the first template glue and the second template glue 10 may be formed of the same material or different materials. In addition, a thickness of the second template glue 10 coated in the second splicing area 7 may be the same as or different from a thickness of the first template glue coated in the first splicing area 6. Apparently, in order to minimize or even eliminate the segment difference between the first splicing imprint pattern 8 and the subsequently formed second splicing imprint pattern, the coating thickness of the second template glue is the same as that of the first template glue.

At step S104, the second template glue is patterned by a preset cavity template (the second cavity template).

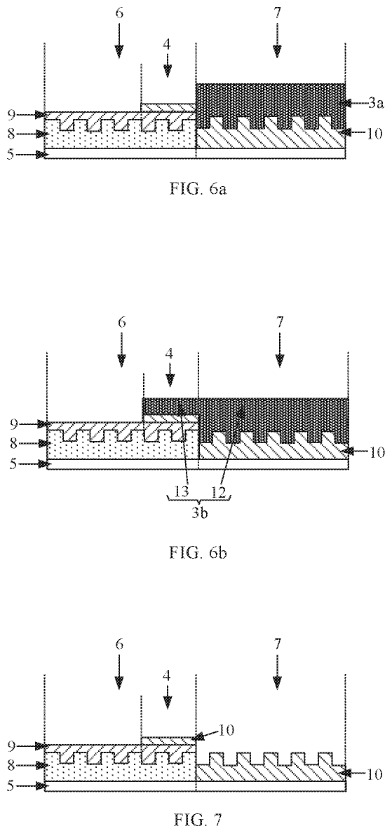

FIG. 6a is a schematic cross-sectional view illustrating patterning the second template glue. As shown in FIG. 6a, the second template glue 10 is imprinted by a preset cavity template 3a to be patterned.

As an alternative implementation, in FIG. 6a, the preset cavity template 3a is aligned with the second splicing area 7 to pattern the second template glue 10 in the second splicing area 7. During this imprinting process, a portion of the second template glue 10 may overflow into the first splicing area 6.

It should be noted that, in the actual production process, the overflowed second template glue may go beyond the preset overlap area 4 due to some accidental factors. At this time, if the sacrificial layer is disposed only in the preset overlap area 4, the second template glue overflowing out of the preset overlap area 4 will directly contact the imprint surface of the first splicing imprint pattern 8. To overcome the above problem, it is preferred in the present disclosure that the sacrificial layer 9 completely covers a side surface of the first splicing imprint pattern 8 facing away from the base substrate 5, i.e., the sacrificial layer 9 covers the entire first splicing area. In this manner, the second template glue 10 is completely prevented from contacting the imprint surface of the first splicing imprint pattern 8 during the imprinting process.

When the preset cavity template 3a shown in FIG. 6a is used to imprint the second template glue 10, the second template glue 10 in the preset overlap area 4 will generate a force on the side surface of the preset cavity template 3a close to the first splicing area 6, which may cause the preset cavity template to be tilted during the imprinting process, thereby affecting the imprinting effect of the second template glue 10 in the second splicing area 7.

To solve the above problem, the present disclosure provides another technical means for patterning the second template glue 10.

FIG. 6b is another schematic cross-sectional view illustrating patterning the second template glue. As shown in FIGS. 6b and 9, the preset cavity template 3b includes: a first imprint structure 12 and a second imprint structure 13 connected to each other. The first imprint structure 12 includes: a support layer 12a, and an imprint pattern layer 12b located on and protruding from a first surface of the support layer. The second imprint structure 13 extends out of the support layer along a direction parallel to the first surface, and is located on a side of a plane of the first surface facing away from the imprint pattern layer so that a distance exists between a surface (lower surface as shown in FIG. 6b), close to the imprint pattern layer 12b, of the second imprint structure 13 and the first surface. This distance enables part of the second template glue to smoothly overflow to a side of the sacrificial layer facing away from the base substrate. In contrast to the illustration in FIG. 6a, the second template glue 10 overflowing into the preset overlap area 4 in FIG. 6b is also imprinted by a preset cavity template 3b.

The specific process of patterning the second template glue 10 by the preset cavity template 3b shown in FIG. 6b includes the following specific steps. First, the preset cavity template 3b is aligned to the second template glue 10, wherein an orthographic projection of the first imprint structure 12 on the base substrate 5 covers the second splicing area 7, and an orthographic projection of the second imprint structure 13 on the base substrate 5 falls into an orthographic projection of the sacrificial layer on the base substrate (i.e., covers at least the preset overlap area 4). Then, the second template glue 10 is imprinted by the preset cavity template 3b to pattern the second template glue 10 in the second splicing area 7. Since the side surface of the preset cavity template 3b is no longer in contact with the second template glue 10, the problem of the tilted preset cavity template 3b during the imprinting process is avoided.

It should be noted that since the second template glue 10 in the preset overlap area 4 is removed in a subsequent process, whether the second template glue 10 in the preset overlap area 4 is imprinted or patterned in step S104 is not limited in the technical solution of the present disclosure. In the present disclosure, it is only necessary to ensure that the second template glue 10 in the second splicing area 7 is imprinted and patterned. The structure of the preset cavity template is not limited herein, and the structure for patterning may be the same as or different from the structure for patterning of the first cavity template.

At step S105, the second template glue is cured and demolded.

FIG. 7 is a schematic cross-sectional view illustrating separating the preset cavity template from the second template glue. As shown in FIG. 7, the second template glue 10 may be cured through a thermal curing or photo curing process, and after the curing process is completed, the preset cavity template is separated from the second template glue 10 through a demolding process.

At step S106, the sacrificial layer is removed through a specific film removing process so that the second template glue on a side of the sacrificial layer facing away from the base substrate falls off, and so that the second template glue in the second splicing area forms a second splicing imprint pattern.

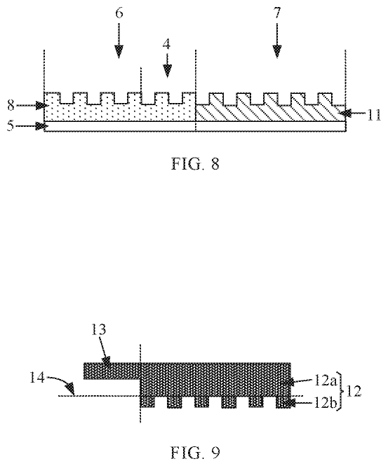

FIG. 8 is a schematic cross-sectional view illustrating removing the sacrificial layer through a specific film removing process to obtain a first splicing imprint pattern and a second splicing imprint pattern. As shown in FIG. 8, when the sacrificial layer 9 is removed through a film removing process, the second template glue 10 on a side of the sacrificial layer 9 facing away from the base substrate 1 will simultaneously fall off, and the second template glue 10 in the second splicing area 7 forms the second splicing imprint pattern 11.

It should be noted that, in step S106, in order to ensure that the second template glue 10 on the side of the sacrificial layer 9 facing away from the base substrate 1 can smoothly fall off following the removal of the sacrificial layer 9, when step S104 is finished, it is to be ensured that a small amount of glue is connected between the second template glue 10 on the side of the sacrificial layer 9 facing away from the base substrate 1 and the second template glue 10 in the second splicing area 7 (after curing, even if there is a small amount of glue connecting the second template glue 10 in the preset overlap area 4 and the second template glue 10 in the second splicing area 7, the small amount of connecting glue will break after the sacrificial layer is removed).

Preferably, when step S104 is finished, the second template glue 10 on the side of the sacrificial layer 9 facing away from the base substrate 1 and the second template glue 10 in the second splicing area 7 are completely separated, that is, the amount of glue connecting the second template glue 10 on the side of the sacrificial layer 9 facing away from the base substrate 1 and the second template glue 10 in the second splicing area 7 is 0. As an alternative implementation, when the preset cavity template shown in FIG. 6b is used to imprint the second template glue, a side of the first imprint structure facing the second imprint structure and a side of the first splicing imprint pattern facing the second splicing area in the preset cavity template are located on the same plane during the imprinting process. At this time, after the imprinting is finished, it can realized that the second template glue 10 on the side of the sacrificial layer 9 facing away from the base substrate 1 and the second template glue 10 in the second splicing area 7 are completely separated.

In actual production, when step S104 is finished, the amount of glue connecting the second template glue 10 on the side of the sacrificial layer 9 facing away from the base substrate 1 and the second template glue 10 in the second splicing area 7 may be detected. If there is a large amount of glue, the glue may be removed by a plasma etching process when step S105 is finished so that the second template glue 10 on the side of the sacrificial layer 9 facing away from the base substrate 1 and the second template glue 10 in the second splicing area 7 are separated, and so that the second template glue 10 on the side of the sacrificial layer 9 facing away from the base substrate 1 can smoothly fall off after the sacrificial layer 9 is removed.

As an alternative implementation, the sacrificial layer 9 is made of a degradable material, and may be degraded through a degradation process in step S106. For example, the degradable material includes a degradable imprint glue that contains a ketal or acetal group, and the ketal or acetal functional group in the cross-linking group is unstable under weak acid conditions after the degradable imprint glue is cured. In step S106, the imprint template may be placed in a weak acid environment (e.g., immersed in a weak acid solution) so that the cross-linking group is hydrolyzed under the weak acid condition, the cross-linking bonds are broken, and the insoluble network structure is changed into a soluble linear structure, thereby achieving the purpose of degradation.

As another alternative implementation, the sacrificial layer 9 is made of a water soluble material, and may be dissolved by an aqueous solvent in step S106.

There is no segment difference between the first splicing imprint pattern 8 and the second splicing imprint pattern 11 prepared through the above steps S101 to S106.

After the sacrificial layer 9 is degraded through a degradation process or dissolved by an aqueous solvent, some water will be left on surfaces of the first splicing imprint pattern 8, the second splicing imprint pattern 11, the base substrate 5 or other structures. In order to avoid the influence of the left water on the subsequent process, in the embodiment, it is preferred that the imprint template is dried after the sacrificial layer 9 is removed; for example, by purging the surface of the imprint template with nitrogen.

It should be noted that the splicing imprint template of the present disclosure includes two or more splicing areas. When two splicing areas are included, the foregoing steps S101 to S106 only need be executed once; and when more than one splicing areas are included, part or all of the above steps S101 to S106 need to be repeatedly executed so that a first splicing imprint pattern and a second splicing imprint pattern are formed in any two adjacent splicing areas (one is the first splicing area and the other is the second splicing area), respectively. Therefore, on the finished splicing imprint template, no segment difference exists between the splicing imprint patterns in any two adjacent splicing areas.

In an embodiment of the present disclosure, there is provided a splicing imprint template, which can be prepared by the preparation method provided in the foregoing embodiments, and the detailed description may be referred to the foregoing.

FIG. 9 is a schematic cross-sectional view of a cavity template provided by an embodiment of the disclosure. As shown in FIG. 9, the cavity template includes: a first imprint structure 12 and a second imprint structure 13 connected to each other. The first imprint structure 12 includes: a support layer 12a, and an imprint pattern layer 12b located on and protruding from a first surface (the lower surface of the support layer 12a in FIG. 9 indicated by the broken line 14) of the support layer. The second imprint structure 13 extends out of the support layer along a direction parallel to the first surface, and is located on a side of a plane of the first surface facing away from the imprint pattern layer 12b so that a distance exists between a surface (the lower surface of the second imprint structure 13 in FIG. 9), close to the imprint pattern layer 12b, of the second imprint structure 13 and the first surface 12a. Due to this distance, a containing part capable of containing the overflowed glue is formed between the lower surface of the second imprint structure 13 and the first surface 14 during the imprinting process, thereby avoiding the segment difference in the imprinting process.

The cavity template provided by this embodiment can be used for imprinting and patterning the second template glue in the foregoing embodiments. The specific imprinting process may be referred to the description of FIG. 6b.

Considering that the second template glue overflowing into the preset overlap area is not patterned, the imprint surface of the second imprint structure may be designed to be a plane, so as to facilitate preparation of the cavity template.

Optionally, the first and second imprint structures are integrally formed. As a preparation method of the cavity template, a glass substrate may be directly etched for one or more times to obtain the first imprint structure and the second imprint structure.

It will be appreciated that the above implementations are merely exemplary implementations for the purpose of illustrating the principle of the disclosure, and the disclosure is not limited thereto. Various modifications and improvements can be made by a person having ordinary skill in the art without departing from the spirit and essence of the disclosure. Accordingly, all of the modifications and improvements also fall into the protection scope of the disclosure.

1. A preparation method of a splicing imprint template, wherein the splicing imprint template comprises: a first splicing area and a second splicing area adjacent to each other, and the preparation method comprises:
forming a first splicing imprint pattern in the first splicing area on a base substrate;
forming a sacrificial layer on a side surface of the first splicing imprint pattern facing away from the base substrate, the sacrificial layer covering at least part of the first splicing area close to the second splicing area, and the sacrificial layer, the first splicing imprint pattern and a second splicing imprint pattern to be formed subsequently being configured such that under a film removing process, the sacrificial layer is removed while the first splicing imprint pattern and the second splicing imprint pattern remain;
forming a second template glue in the second splicing area on the base substrate;
patterning the second template glue in the second splicing area by a cavity template;
curing and demolding the second template glue; and
removing the sacrificial layer by the film removing process.

2. The preparation method according to claim 1, wherein the sacrificial layer covers the entire first splicing area.

3. The preparation method according to claim 1, wherein a material of the sacrificial layer comprises: a degradable material; and
the step of removing the sacrificial layer through the film removing process comprises: degrading the sacrificial layer through a degradation process.

4. The preparation method according to claim 3, wherein the degradable material comprises: a degradable imprint glue.

5. The preparation method according to claim 1, wherein a material of the sacrificial layer comprises: a water soluble material; and
the step of removing the sacrificial layer through the film removing process comprises: dissolving the sacrificial layer with an aqueous solvent.

6. The preparation method according to claim 5, wherein the water soluble material comprises: at least one of a polyvinyl alcohol resin and a polycaprolactone resin.

7. The preparation method according to claim 3, wherein after the step of removing the sacrificial layer through the film removing process, the method further comprises:
drying the imprint template.

8. The preparation method according to claim 1, wherein the cavity template comprises: a first imprint structure and a second imprint structure connected to each other; the first imprint structure comprises: a support layer, and an imprint pattern layer located on and protruding from a first surface of the support layer; the second imprint structure extends out of the support layer along a direction parallel to the first surface, and is located on a side of a plane of the first surface facing away from the imprint pattern layer so that a distance exists between a surface, close to the imprint pattern layer, of the second imprint structure and the first surface; and
the step of patterning the second template glue in the second splicing area by the cavity template comprises:
aligning the cavity template to the second template glue, wherein an orthographic projection of the first imprint structure on the base substrate covers the second splicing area, and an orthographic projection of the second imprint structure on the base substrate falls into an orthographic projection of the sacrificial layer on the base substrate; and
imprinting the second template glue by the cavity template to pattern the second template glue in the second splicing area.

9. The preparation method according to claim 8, wherein during the process of patterning the second template glue in the second splicing area by the cavity template, a side of the first imprint structure facing the second imprint structure is located on the same plane as a side surface of the first splicing imprint pattern facing the second splicing area.

10. A cavity template, comprising: a first imprint structure and a second imprint structure connected to each other; wherein
the first imprint structure comprises: a support layer, and an imprint pattern layer located on and protruding from a first surface of the support layer; and, the second imprint structure extends out of the support layer along a direction parallel to the first surface, and is located on a side of a plane of the first surface facing away from the imprint pattern layer so that a distance exists between a surface, close to the imprint pattern layer, of the second imprint structure and the first surface.

11. The cavity template according to claim 10, wherein an imprint surface of the second imprint structure is a plane.

12. The cavity template according to claim 10, wherein the first and second imprint structures are integrally formed.
